(19) United States
(12) Patent Application Publication
(10) Pub. No.: US 2009/0243088 A1
(43) Pub. Date: Oct. 1, 2009

(54) Multiple Layer Metal Integrated Circuits and Method for Fabricating Same

(75) Inventor: Joel Lee Goodrich, Westford, MA (US)

Correspondence Address: CHRISTOPHER P. MAIORANA, P.C., 24840 HARPER SUITE 100, ST. CLAIR SHORES, MI, 48080, US

(73) Assignee: M/A-Com, Inc., Lowell, MA (US)

(21) Appl. No.: 12/057,783

(22) Filed: Mar. 28, 2008

(51) Int. Cl. H01L 23/48; H01L 21/4763

(52) U.S. Cl. 257/734; 438/631; 257/E23.01

(57) ABSTRACT

A method of fabricating a plurality of layers of metal on a substrate depositing a first layer of metal on the substrate; depositing a first layer of planarization material over the substrate and first layer of metal to a depth above the top of the first layer of metal; polishing the first layer of planarization material down to at least the top of the first layer of metal; and depositing a second layer of metal on the first layer of metal and the first layer of planarization material.

### FIELD OF THE INVENTION

The invention pertains to integrated circuits and the fabrication thereof. More particularly, the invention pertains to integrated circuits with multiple layers of metal and the fabrication thereof.

### BACKGROUND OF THE INVENTION

Heterolithic microwave integrated circuits (HMIC's) are one viable approach to low-cost, mass-produced integrated circuits for radio frequency (RF) and microwave applications. In HMICs as well as other integrated circuits, layers of metal commonly are placed on the surface of the integrated circuit and patterned to provide necessary circuit components. For instance, metal is commonly used to form contact pads for connecting to circuitry external of the integrated circuit chip, to form plates of capacitors, to form inductor windings, and to form conductive paths between other circuit components on and off the chip, such as, but not limited to, simple conductors, microstrips, strip lines, and wave guides.

Integrated circuit designers have resorted to countless innovations in efforts to increase the amount of circuitry that can be fabricated in a given area. One technique for increasing circuit density on integrated circuits is the fabrication of circuitry in multiple layers on top of a substrate. However, one of the problems associated with increasing the number of layers that are deposited and etched on top of a substrate is that the layers of semiconductors, dielectrics, metals, etc. that are deposited on top of a substrate typically are patterned (i.e., material exists in some places and not in others), and, therefore, are not planar, but rather create topography on the substrate. The topography of each layer usually is additive such that each additional layer tends to increase the level of variation in the topography. Variations in the topography of a layer make it more difficult to accurately pattern the layer using a photolithography mask since, if the layer that is exposed through a photolithography mask is not perfectly planar, then the mask pattern will not transfer perfectly to the underlying wafer surface. Thus, as the planarity of the layer decreases, the resolution of the circuit components that can be formed in that layer decreases, thereby either requiring the upper layers to have larger circuit components or entirely preventing the effective fabrication of circuit components thereon.

### SUMMARY OF THE INVENTION

A method of fabricating a plurality of layers of metal on a substrate depositing a first layer of metal on the substrate; depositing a first layer of planarization material over the substrate and first layer of metal to a depth above the top of the first layer of metal; polishing the first layer of planarization material down to at least the top of the first layer of metal; and depositing a second layer of metal on the first layer of metal and the first layer of planarization material. If desired, a second layer of planarization material may be deposited over the second layer of metal (and first layer of planarization material) and polished down to the top of the second layer of metal. This may be repeated to add as many more layers as desired with no increase in metal feature size required.

### BRIEF DESCRIPTION OF THE DRAWINGS

FIGS. 1A-1H are cross-sectional elevation views of an exemplary HMIC during various stages of fabrication in accordance with the principles of the present invention.

FIG. 2 is a top plan view of a completed HMIC in accordance with the principles of the present invention.

### DETAILED DESCRIPTION OF THE INVENTION

It would be desirable to be able to increase the number of layers of metal that can be deposited and patterned with high resolution during semiconductor fabrication in order to increase the amount of circuitry that can be formed on a given area of an integrated circuit.

In accordance with the principles of the present invention, this can be accomplished by planarizing an underlying metal layer prior to depositing the next metal layer thereon. Particularly, in accordance with the invention, a metal layer is planarized to a high degree by encapsulating the metal layer in a material having good planarization properties, such as BCB (benzocyclobutene), and then polishing down to re-expose the top surface of the metal. The next layer of metal can be deposited and patterned on top of the planarization material and the metal layer.

The invention permits more circuitry to be formed in a given semiconductor substrate area, not only because it permits more layers of circuitry to be formed on top of each other, but also because it permits the resolution of the circuitry to remain extremely high (thus allowing for smaller circuit components). The invention also facilitates the use of more corrosion sensitive, but lower cost and higher conductivity metals such as copper and silver versus the current predominantly used gold because each layer of metal is environmentally sealed. Thus, for instance, gold often is used as a metal in semiconductor fabrication instead of the much lower cost copper because gold is more corrosion resistant than copper. This invention will allow a circuit designer to simultaneously improve the performance and lower the cost of his or her circuit by using copper or silver instead of gold.

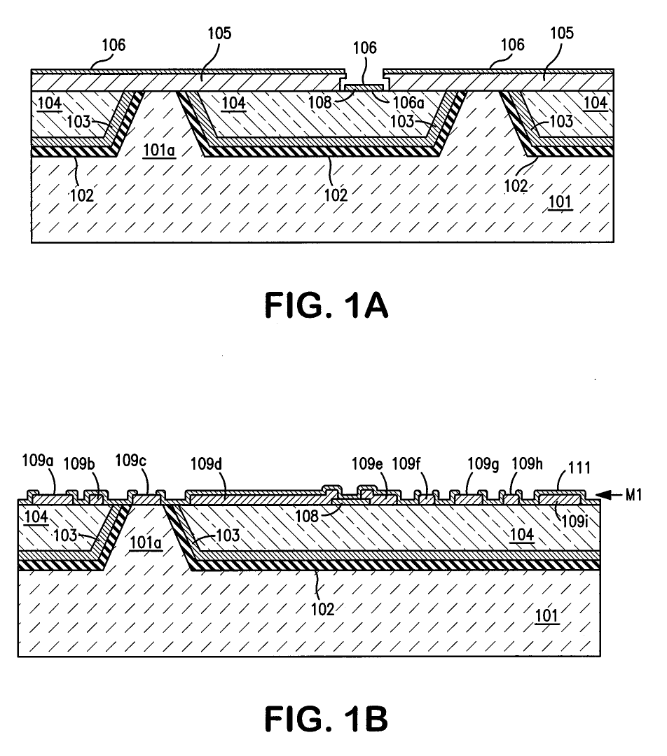

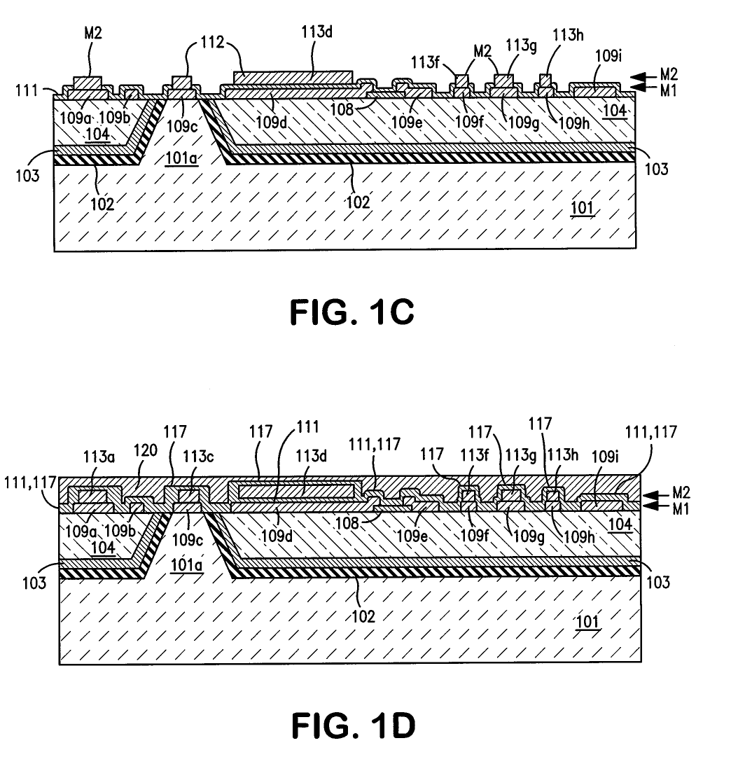

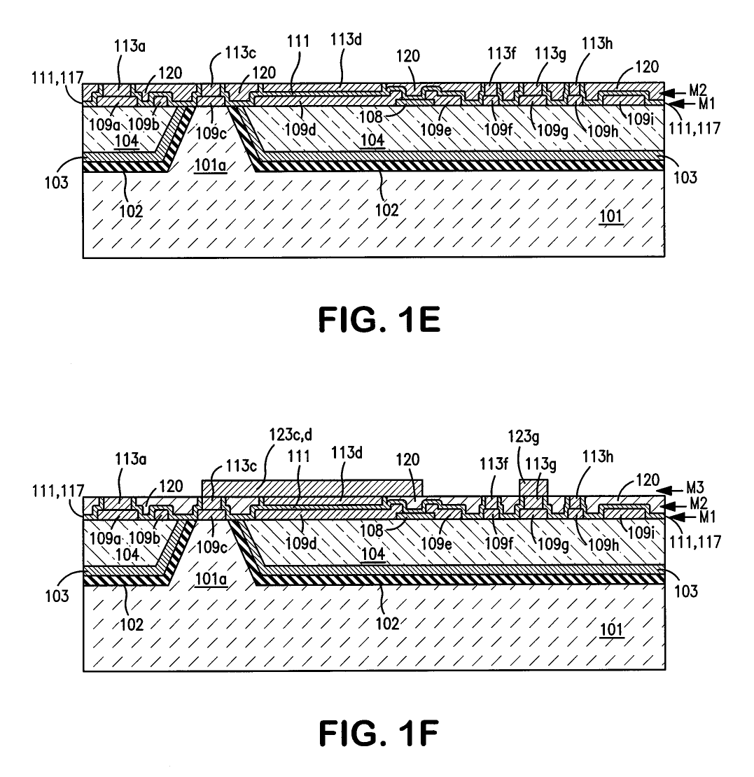

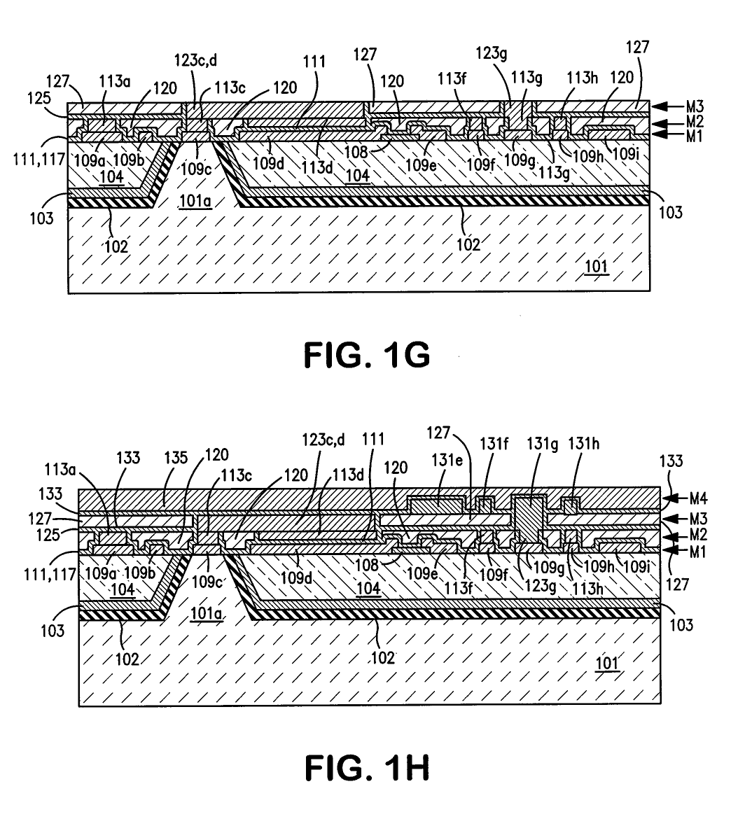

FIGS. 1A-1H illustrate various stages of an exemplary process for fabricating a heterolithic microwave integrated circuit in accordance with the principles of the present invention.

Referring to FIG. 1A, it shows a glass or glass-silicon integrated circuit wafer 100 in a partially-fabricated, beginning state, particularly, a glass or glass-silicon substrate 101 with a via forming a pedestal 101a and with a higher conductivity layer 102 (e.g., an n+diffusion or preferably a metal or metal silicide region) provided therein. A silicon nitride layer 103 has been deposited on top of the higher conductivity layer. Next, a layer of glass 104 has been deposited to and polished down to the level of the silicon surface of the pedestals to provide a planar starting surface.

Next, resistors are formed on the glass 104. Particularly, a layer of photoresist 105 is deposited and patterned. For instance, the wafer is spin coated with a photoresist 105, preferably to a thickness that is at least 0.5 microns thicker than the metal layer that will be used to form the resistors. The photoresist 105 is baked and then immersed in or spray coated with photoresist developer to create a slower developing layer of photoresist at the top of the photoresist. After rinsing and drying, the photoresist 105 is exposed. Next, the wafer is put through a post-exposure bake.

The photoresist 105 is developed, resulting in a photoresist profile in the particular exemplary process discussed herein having an overhanging lip at the top of the photoresist (as a result of the immersion or spray coating of the photoresist with the developer as just described) such as shown at 130 in FIG. 1A. This forms a shadow mask that ensures that the resistor metal will be discontinuous between the top surface of the photoresist and the substrate.

Next, the resistor metal layer 106 (e.g., nichrome) is evaporated onto the wafer 100. Accordingly, the resistor metal layer 106 is deposited on top of the photoresist layer 105, as well as on top of the glass 104 where the photoresist has been patterned, as shown at 106a. In FIG. 1A, only one resistor 108 is seen.

FIG. 1A shows the wafer at this stage of the fabrication process.

Next, the remaining photoresist 105 is dissolved, thereby removing all of the metal 106 that was deposited on top of the photoresist 105 and leaving the metal portion 106a that formed directly on top of the glass or substrate. The remaining resistor metal 106(a) constitute the resistor(s) 108.

Referring now to FIG. 1B, the next series of steps are designed to deposit the first layer of metal on the wafer. The first layer of metal can serve many different purposes depending on the particular circuit that is being fabricated. In the exemplary circuit illustrated in the figures, the first layer of metal 109 will form several different circuit features. Particularly, as will be seen, the first layer of metal will form (1) portions of contacts to the resistor(s), (2) the bottom plate(s) of MIM capacitor(s), and (3) portions of windings of inductors.

The first layer of metal 109 is deposited and patterned essentially using conventional techniques. Any suitable fabrication technique can be used. For example, photoresist (not shown) may be deposited and patterned and then the first metal layer 109 deposited over the patterned photoresist. The first metal layer may be any thickness. In this exemplary embodiment, it is about 2.5 microns. Furthermore, as is well known in the art, the metal layer may actually comprise several layers of different metals. For instance first metal layer 109 may actually comprise a thin layer of titanium followed by a thin layer of platinum before the primary metal (copper or gold) is deposited. Particularly, it is well-known to deposit titanium to act as an adhesion layer followed by platinum to act as a diffusion barrier before depositing the high conductivity, primary metal (which commonly is copper, silver, or gold). The photoresist is then removed, leaving the desired metal pattern on the wafer. Next, the surface of the wafer is encapsulated by plasma enhanced chemical vapor deposition (PECVD) of silicon nitride 111. The silicon nitride 111 is a dielectric that will form, for instance, the insulating layer between the bottom plates of the capacitors (as formed from the first metal layer 109) and the top plates of the capacitors (which will be formed with the second layer of metal). The silicon nitride layer 111 is plasma etched to remove only the areas where contact is desired between the first metal layer and the second metal layer. This, for instance, might be the portions of the first metal layer that will serve as parts of bond pads or conductive vias to other, overlying metal layers or conductors that need to be thicker than a single layer of metal in order to carry large currents. FIG. 1B shows the wafer at this stage of the fabrication process.

Thus, for instance, in FIG. 1B, the portions 109a, 109c, 109f, 109g, and 109h of first metal layer 109 are exposed through etching of the silicon nitride layer. Therefore, they will form circuit components that connect to the second metal layer. These may be, parts of bond pads or parts of metal components that need to be thicker than a single metal layer. On the other hand, portions 109b, 109d, 109e, and 109i, which are covered with silicon nitride 111 will not make conductive contact to any metal layer to be deposited thereover. Note that first metal layer portions 109d and 109e are the contacts to the resistor 108. However, one or both also could simultaneously form the bottom plates of a capacitor (as will be the case for portion 109d).

Turning now to FIG. 1C, the second metal layer 113 is deposited. Again, second metal layer 113 is deposited largely in the same manner as described above in connection with the first metal layer 109. Particularly, photoresist (not shown) is deposited and patterned to create the desired pattern for the second layer of metal. Then, the wafer is coated with a second layer of metal 113, whereby second metal layer 113 deposits on top of the photoresist in those portions where the photoresist remains and is deposited on top of the silicon nitride 111 or first metal layer 109 in those portions of the photoresist that has been patterned away. In the exemplary embodiment, second metal layer 113 also is about 2.5 microns thick. In a preferred embodiment of the invention, the second metal layer actually comprises four layers, namely, titanium, platinum, copper, and another layer of platinum. The copper is the thickest layer and is the functional layer of the second metal layer. The three other layers, are very thin and are incorporated to simplify processing. As described for the first metal layer, 109, the first layer is titanium for adhesion. The platinum layers above and below the conductor layer inhibit diffusion of the conductor layer.

FIG. 1C shows the wafer at this stage of the process. As can be seen, the second layer of metal 113 has been patterned such that it is in contact with the first metal layer 109 at portions 109a, 109c, 109f, 109g, 109h. Second metal layer 113 also has been deposited over the silicon nitride layer 111 above the resistor contact portion 109d. Accordingly, a capacitor has been formed wherein the first metal layer portion 109d is the lower plate of the capacitor and second metal layer portion 113d is the upper plate of the capacitor. No metal from second metal layer 113 has been deposited over first metal layer portions 109b, 109e, and 109i. Thus, portions 109b, 109e, and 109c of first metal layer 109 may be conductor lines between two circuit components on the wafer. (It should also be understood that FIGS. 1A-1F are cross-sectional elevation views that show only a slice of the wafer: Thus, it is possible that portions 109b, 109c, and/or 109f may connect with the second metal layer 113 elsewhere on the wafer in places not visible in this particular cross-sectional slice).

The second metal layer 113, and particularly, different portions of the second metal layer, may serve different functions. For instance, portions of the second metal layer may serve to increase the thickness of the first layer of metal in order to provide a circuit feature having lower resistance than if the feature were made with only one metal layer. As seen in FIG. 1C, other portions such as portion 113d may form the top electrode of a MIM capacitor. Even further, other portions may serve to connect to portions of the first metal layer 109 with portions of the third metal layer (and possibly even a fourth and any subsequent metal layers).

Turning now to FIG. 1D, another plasma enhanced chemical vapor deposition (PECVD) of silicon nitride 117 is performed to encapsulate the first and second metal layers. Note that silicon nitride layer 117 is directly on top of silicon nitride layer 111 in most places except for at the tops of the portions of the second metal layer, e.g., portions 113c, 113d, 113f, 113g, and 113h. Particularly, at the tops of the portions of the second metal layer they are either separated from each other by the second metal layer (e.g., see portion 113d separating layers 111 and 117) or the first silicon nitride layer 111 had previously been etched away e.g., see portions 113c, 113f, 113g, and 113h. However, at this point, the process departs from convention. Particularly, the silicon nitride film 117 not only serves to encapsulate the first and second metal layers, but also to provide a suitable adhesion surface for a layer of planarization material. Specifically, in accordance with the invention, a layer of encapsulating material 120 having good planarization properties, such as benzocyclobutene (BCB), is deposited on top of the silicon nitride layer 117 as a planarization layer. In one particular embodiment, the planarization layer 120 is BCB deposited by a spin coat process. However, it can be deposited by other techniques also. The BCB planarization layer 120 is targeted to be at least a thickness above the substrate of the highest point of any preexisting layer(s) or, preferably, slightly thicker. In this case, this would be the combined thickness of first metal layer 109, the first silicon nitride layer 111, and second metal layer 113, which is at 5.8 microns (first metal layer=2.7 microns, silicon nitride layer=0.3 microns, and second metal layer=2.8 microns). FIG. 1D illustrates the condition of the wafer after the BCB has been deposited.

purpose of the BCB planarization layer 120 is to fill the spaces between the features formed of the first and second metal layers 109 and 113 with BCB (thus, it must be at least as thick as the cumulative depth of those features), but minimize the amount of polishing required to expose the top of the second metal layer 113 through the BCB planarization layer 120 and silicon nitride layer 117. The BCB planarization layer 120 and silicon nitride 117 are polished down to the level at which the top of the second metal layer 113 is exposed. FIG. 1E shows the condition of the wafer after polishing.

After polishing, the wafer is once again planar with the BCB filling in the spaces that would otherwise exist between the various portions of the second metal layer. A megasonic assisted copper clean can be performed to remove the polishing slurry to better prepare the wafers for the next layer of metal.

Particularly, at this point, the top surface of the wafer is planar and a third metal layer 123 can be deposited essentially exactly like the first metal layer 109 was deposited on the planar surface of the substrate 101. The third metal layer will not have any topography to deal with that might adversely affect the ability to pattern it.

More particularly, with reference to FIG. 1 F, another layer of photoresist is deposited and patterned and the third metal layer 123 is deposited over it. The photoresist is washed away leaving the portions of the third metal layer, such as portions 123c,d and 123g on the wafer. The various portions of the third metal layer can serve any number of functions in the circuit. For instance, some portions can provide crossovers of corresponding portions of the first metal layer, such as third metal layer portion 123c,d. Other portions can provide connections to the top electrodes of any MIM capacitors. Even further, they can provide connection between the second metal layer (or first and second metal layers) on the one hand and any subsequent metal layer(s), such as will be seen is the case for portion 123g.

The portions of each given metal layer, e.g., 109, 113, 123, are labeled with common reference numerals and the different portions of metal within a given layer of metal are followed by one or more letter reference characters. The letter characters used in the second, third, and fourth metal layers 113, 123, and 131 have been selected to correspond generally to the letter reference character(s) of the portion(s) of the first metal layer that it overlies. For example, metal portions 123c,d and 123g share the same numeric portion (123) because they are both portions of the same metal layer 123. Portion 123c,d is designated by letter combination “c,d” because it overlies both metal portions 109c and 109d of the first metal layer 109 and portion 123g is designated by letter “g” because it overlies metal portion 109g of the first metal layer. This reference character convention has been selected merely for convenience and is not intended to signify anything about the various metal portions. For instance, it is certainly likely that, in a practical circuit, there may be meal portions that do not overlie any portions of the underlying metal layers or overlie multiple portions of underlying metal layers or overlie portions of underlying metal layers in some places and not in others. For instance, it can be seen that while portion 123c,d of the third metal layer 123 has been so designated because it overlies both portions 109c and 109d of first metal layer 109, it also overlies resistor 108 and the space between first metal layer portions 109c and 109d. No meaning should be taken from these reference characters,

Next, the surface of the wafer is again encapsulated in another silicon nitride layer 125 and another BC planarization layer 127 is deposited on top of the silicon nitride 125. This second BCB planarization layer 127 is polished essentially exactly as described above in connection with the previous BCB planarization layer 120 to expose the tops of third metal layer portions 123d, 123g. The polishing of the third metal layer 123 is actually simpler than the polishing of the second metal layer 113 since there is less variation in the topography because there is no topography due to the nitride layer as there was with respect to the second metal layer 113, only topography due to the third metal layer third metal layer 123 on top of the planar surface comprised of the second metal layer 113 and the first BCB planarization layer 120. Once again, after polishing and a megasonic assisted copper clean, the wafers are planar as shown in FIG. 1G and ready for another layer of metal, i.e., the fourth metal layer 131, as shown in FIG. 1G.

A fourth metal layer 131 may be deposited on the planar surface of the wafer essentially as described above in connection with the third metal layer 123.

Different portions of the fourth metal layer 131 can serve different functions. For instance, with reference to FIG. 1H, they can provide crossovers of the second metal layer, such as portion 131e. Other portions, like portion 131g, can be in direct contact with the underlying metal layers 109, 113, 123 to collectively form a conductive via down to the substrate or any underlying layers (not shown). Additionally, portions of the fourth metal layer can form an additional winding of a multilayer spiral tinductor or transformer, such as portions 131f and 131h (note that 131f and 131h are two points of the same winding, which intersect the cross-sectional plane of FIG. 1H in two places, namely, 131f and 131h). Particularly, with the technique of the present invention, which allows essentially any reasonable numbers of layers of metal to be deposited on top of each other, much larger inductors or transformers can be produced in the same area by fabricating multiple windings on top of each other. For instance, as can be seen in FIG. 1H, an inductor can be formed of a first set of thicker windings formed of the first and second metal layer, e.g., portions 109f, 109h, 113f, 113h, plus additional windings in the fourth metal layer, e.g., 131f, 131h. The windings in the first metal layer and the windings in the fourth metal layer are connected by the conductive via formed through all four metal layers by portions 109g, 113g, 123g, and 131g.

As the final steps, fourth metal layer 131 is coated with a final encapsulating silicon nitride layer 133 and BCB planarization layer 135 essentially as described previously in connection with second and third metal layers, except the BCB and silicon nitride are not polished.

The present invention permits a theoretically unlimited number of metal layers to be stacked. After each planarization step, the top of the wafer is essentially as planar as the original substrate surface.

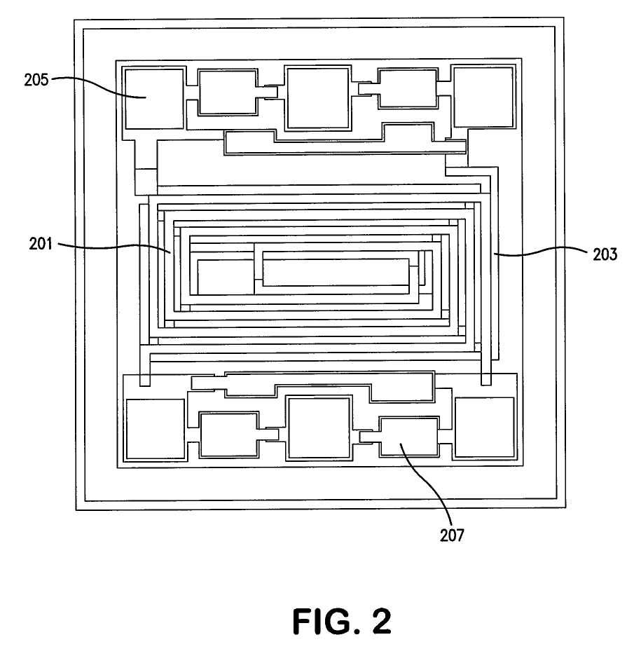

Before the wafer is diced, the BCB and silicon nitride layers should be removed from the dicing streets and the first metal layer bond pads if necessary. FIG. 2 is a top plan view in which some portions of the various metal layers 109, 113, 123, 131 are visible through the BCB and silicon nitride layers. Particularly, the top inductors formed in the fourth metal layer 131 are shown at 201. The lower inductor coils formed in first metal layer 109 and second metal layer 113 can be partially seen beneath them at 203. Shown at 205 is a portion of the first metal layer that forms a bond pad. Reference numeral 207 shows a portion of third metal layer 123 that forms the top plate of a capacitor, the other plate being formed in first metal layer beneath 207.

By using the principles of the present invention, one can create more circuitry in the same area by stacking circuit components vertically. In addition, one can make thicker layers of metal without sacrificing resolution. This permits increasing the conductivity of a metal feature by making the metal feature thicker, without the need to increase the area of the feature. It simultaneously allows designers to lower the cost and increase the performance of their circuits by replacing more expensive gold with lower cost and more conductive copper as described above for example.

Having thus described a few particular embodiments of the invention, various alterations, modifications, and improvements will readily occur to those skilled in the art. Such alterations, modifications, and improvements as are made obvious by this disclosure are intended to be part of this description though not expressly stated herein, and are intended to be within the spirit and scope of the invention. Accordingly, the foregoing description is by way of example only, and not limiting. The invention is limited only as defined in the following claims and equivalents thereto.

1. A method of fabricating a plurality of layers of metal on a substrate comprising:
depositing a first layer of metal on the substrate;
depositing a first layer of planarization material over the substrate and first layer of metal to a depth above the top of the first layer of metal;
polishing the first layer of planarization material down to at least the top of the first layer of metal; and
depositing a second layer of metal on the first layer of metal and the first layer of planarization material.

2. The method of claim 1 wherein the first layer of planarization material fills in spaces between portions of the first layer of metal.

3. The method of claim 2 further comprising:
cleaning the substrate after the polishing and before the depositing of the second layer of metal.

4. The method of claim 2 wherein the planarization material is BCB.

5. The method of claim 4 further comprising:
depositing an insulating layer over the substrate and first metal layer before depositing the first layer of planarization material; and
wherein the depositing of the first layer of planarization layer comprises depositing the first layer of planarization layer over the silicon nitride.

6. The method of claim 2, wherein the substrate is a semiconductor wafer.

7. The method of claim 6, wherein the method is used to fabricate a heterolithic microwave integrated circuit.

8. The method of claim 1 further comprising:
depositing a second layer of planarization material over the second layer of metal to a depth above the top of the second layer of metal.

9. The method of claim 8 further comprising:
polishing the second layer of planarization material down to at least the top of the second layer of metal;
depositing a third layer of metal on the second layer of metal and the second layer of planarization material; and
depositing a third layer of planarization material over the second layer of planarization material and second layer of metal to a depth above the top of the second layer of metal.

10. The method of claim 1 wherein the depositing of the first layer of metal comprises depositing at least first and second metal layers and wherein the depositing of the first metal layer comprises depositing a plurality of different metals on top of each other and wherein the depositing of the second metal layer comprises depositing a plurality of different metals on top of each other.

11. A method of fabricating a plurality of metal layers on a semiconductor substrate comprising:
depositing at least a first metal layer on the substrate;
patterning the at least first metal layer to create topographical features of the first metal layer;
depositing a first layer of planarization material over the substrate and first metal layer to a depth above the highest topographical feature of the first metal layer, whereby the first layer of planarization material fills in spaces between the topographical features of the first metal layer;
polishing the first layer of planarization material down to at least the top of lowest topographical feature of the first metal layer; and
depositing a second layer of metal on the first layer of metal and the first layer of planarization material.

12. The method of claim 11 wherein the planarization material is BCB.

13. The method of claim 12 further comprising:
depositing an insulating layer over the substrate and first metal layer before depositing the first layer of planarization material; and
wherein the depositing of the first layer of planarization layer comprises depositing the first layer of planarization layer over the silicon nitride.

14. The method of claim 11 further comprising:
patterning the second metal layer to create topographical features of the second metal layer;
depositing a second layer of planarization material over the second layer of metal to a depth above the highest topographical feature of the second layer of metal:
polishing the second layer of planarization material down to at least the top of the lowest topographical feature of the second metal layer;
depositing a third layer of metal on the second metal layer and the second layer of planarization material;
patterning the third metal layer to create topographical features of the third metal layer; and
depositing a third layer of planarization material over the second layer of planarization material and second layer of metal to a depth above the highest topographical feature of the third metal layer.

15. An integrated circuit comprising:
a substrate bearing circuitry;
a first layer of patterned metal on the substrate forming topographical features;
a first layer of planarization material on the substrate and the first layer of metal, wherein the first layer of planarization material fills in the spaces between the topographical features of the first layer of metal and presents a planar surface along with the first layer of metal at the top thereof;
a second layer of patterned metal on the first layer of metal and the first layer of planarization material.

16. The integrated circuit of claim 15 further comprising a first layer of silicon nitride between the first layer of planarization material on one side and the substrate and first layer of metal on the other side.

17. The integrated circuit of 16 wherein the planarization material is BCB.

18. The integrated circuit of 15 further comprising: a second layer of planarization material over the second layer of metal and first layer of planarization material.

19. The integrated circuit of claim 15 wherein the integrated circuit is a heterolithic microwave integrated circuit.

20. The integrated circuit of claim 18 wherein;
the second layer of planarization material fills in the spaces between the topographical features of the second layer of metal and presents a planar surface along with the second layer of metal at the top thereof;
a third layer of metal on the second layer of planarization material;
a third layer of planarization material over the third layer of metal and second layer of planarization material.

21. The integrated circuit of claim 20 wherein the integrated circuit is a heterolithic microwave integrated circuit.

22. The integrated circuit of claim 19 further comprising:
a second layer of silicon nitride between the second layer of planarization material on one side and the first layer of planarization material and the second layer of metal on the other side; and
a third layer of silicon nitride between the third layer of planarization material on one side and the second layer of planarization material and the third layer of metal on the other side.
